(19) United States
(12) Patent Application Publication
(10) Pub. No.: US 2025/0307508 A1
(43) Pub. Date: Oct. 2, 2025

(54) GENERATING DESCRIPTIONS OF INTEGRATED CIRCUITS USING NEURAL NETWORKS

(71) Applicant: Google LLC, Mountain View, CA (US)

(72) Inventors: Amir Yazdanbakhsh, San Jose, CA (US); Aman Madaan, Pittsburgh, PA (US)

(21) Appl. No.: 18/623,977

(22) Filed: Apr. 1, 2024

(51) Int. Cl. G06F 30/327

(52) U.S. Cl. CPC G06F 30/327

(57) ABSTRACT

Methods, systems, and apparatus, including computer programs encoded on a computer storage medium, for neural network-assisted circuit design for integrated circuits. One of the methods include obtaining a description of an integrated circuit (IC); selecting one or more Boolean expressions specified in the description; and processing the one or more selected Boolean expressions using a neural network to generate an output that comprises one or more alternative Boolean expressions.

### BACKGROUND

This specification relates to integrated circuits (ICs) and, more particularly, to neural network-assisted circuit design for integrated circuits.

A design of an integrated circuit may be specified in a hardware description language, e.g., as a logic-level register transfer level (“RTL”) description, a gate-level description, a layout-level description, or a mask-level description. The RTL description describes a synchronous digital circuit in terms of the flow of digital signals between hardware registers and the operations performed on those signals. The design of the integrated circuit may be processed through a design flow, where the design flow may perform operations such as synthesis, placement, and routing. The processed design may be implemented within an integrated circuit. Neural networks are machine learning models that employ one or more layers of nonlinear units to predict an output for a received input. Some neural networks include one or more hidden layers in addition to an output layer. The output of each hidden layer is used as input to the next layer in the network, i.e., the next hidden layer or the output layer. Each layer of the network generates an output from a received input in accordance with current values of a respective set of parameters.

### SUMMARY

This specification describes a system implemented as computer programs on one or more computers in one or more locations that trains, implements, or both a neural network that processes an input that includes a Boolean expression to generate an output that includes an alternative Boolean expression. The alternative Boolean expression can be a simplified representation that has fewer Boolean operators than the Boolean expression but represents a same logical function as the Boolean expression.

The subject matter described in this specification can be implemented in particular embodiments so as to realize one or more of the following advantages. Logic optimization, which involves minimizing the number of logic gates needed to implement the logical functions of an integrated circuit chip, is a crucial step in the chip design process. For example, logic optimization can improve the power, performance, and area (PPA) metrics for the integrated circuit chip. The described system facilitate improvement over an initial description of integrated circuit, e.g., a Register Transfer Level (RTL) description or a gate-level netlist description that has been generated by a chip designer, in an automated manner with no or minimal human expert involvement, by making use of the described language model neural network and the described training techniques.

Unlike the described systems, conventional logic optimization approaches generally rely on heuristics. However, as chip designs become increasingly larger and more complex, heuristic-based methods may not take into account the enormous space of all possible logical functions and further require that no errors are done when determining the heuristics and, therefore, hardware implementation of logical functions on a chip may not be optimized.

By leveraging the data generation and reasoning capabilities of a language model neural network, the described techniques are able to quickly generate alternative Boolean expressions for inclusion in a modified description of the integrated circuit that generally include fewer Boolean operators than, but nevertheless are logically equivalent to, the Boolean expressions included in the initial description.

Accordingly, an integrated circuit chip which is manufactured in accordance with the modified description may include a reduced number of logic gates and may therefore have reduced power consumption compared to an integrated circuit chip manufactured in accordance with the initial description. It may also have increased computing power for a given surface area, or from another point view make more efficient use of circuit resources to implement the same logical functions.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows an example training system and an example inference system.

FIG. 2 shows an example illustration of a language model neural network generating a network output based on processing a network input.

FIG. 3 is a flow diagram of an example process for training a language model neural network.

FIG. 4 is a flow diagram of an example process for generating an alternative Boolean expression using a language model neural network.

Like reference numbers and designations in the various drawings indicate like elements.

### DETAILED DESCRIPTION

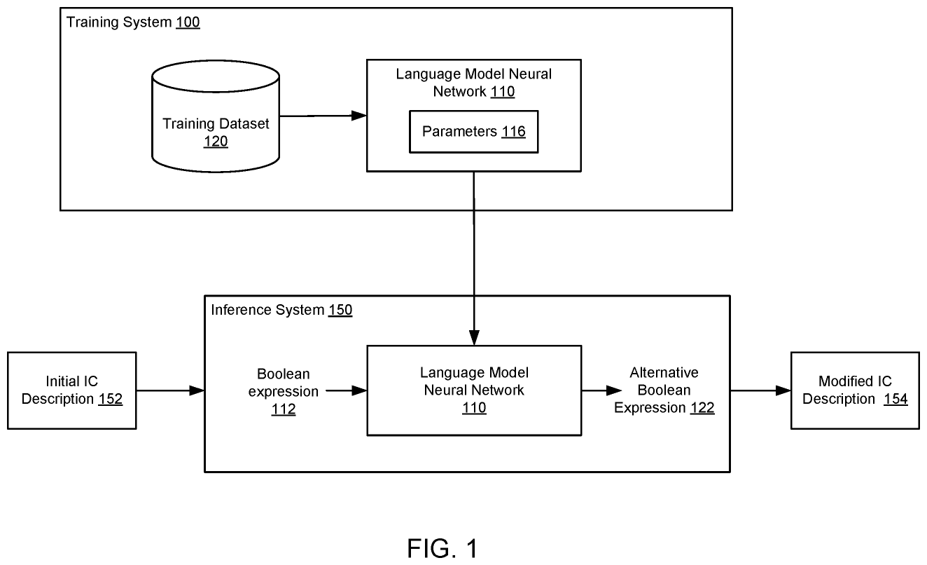

FIG. 1 shows an example training system 100. The training system 100 is an example of a system implemented as computer programs on one or more computers in one or more locations, in which the systems, components, and techniques described below can be implemented.

The training system 100 trains a language model neural network 110 to perform one or more Boolean expression processing tasks by training the neural network 110 on a training dataset 120 to determine trained values of the parameters 116 of the language model neural network 110.

A Boolean expression can include Boolean variables (e.g., “x” or “y” or “x[0]” where 0 indicates the Boolean variable was initially created for timestep zero) and/or Boolean values (e.g., “1” or “0” or “1[0]” where 0 indicates the Boolean value was initially created for timestep zero) connected by Boolean operators. Some examples of a Boolean operator include but are not limited to AND, OR, NOT, XOR, NAND, NOR, etc. A Boolean expression can also be a single Boolean variable or a single Boolean value.

In circuit design, each Boolean operator can correspond to the application of a logical operation on one or more input signals to a component of an integrated circuit and/or one or more output signals of various registers and other memory devices that can be represented by Boolean variables or Boolean values. In other words, a Boolean expression can represent (at least a part of) either a combinational circuit component or a sequential circuit component in the integrated circuit.

One example of such Boolean expression processing tasks is a Boolean expression simplification task. In this example, the language model neural network 110 is configured through training to process a network input that includes a Boolean expression 112 in accordance with the parameters 116 to generate a network output that includes an alternative Boolean expression 122. The alternative Boolean expression 122 is a simplified representation that has fewer Boolean operators than the Boolean expression 112 but represents the same logical function as the Boolean expression 112.

As an example for illustration, a Boolean expression “xy” is a simplified representation of a Boolean expression “x(x′+y)” because the Boolean expression “x(x′+y)” has three Boolean operators (a NOT operator, an AND operator, and an OR operator), whereas the Boolean expression “xy” has one Boolean operator (an AND operator), despite that the Boolean expression “xy” and the Boolean expression “x(x′+y)” are functionally equivalent to each other, e.g., represent the same logical function.

In some implementations, the language model neural network 110 can have any of a variety of Transformer-based neural network architectures. Examples of such architectures include those described in J. Hoffmann, S. Borgeaud, A. Mensch, E. Buchatskaya, T. Cai, E. Rutherford, D. d. L. Casas, L. A. Hendricks, J. Welbl, A. Clark, et al. Training compute-optimal large language models, arXiv preprint arXiv: 2203.15556, 2022; J. W. Rac, S. Borgeaud, T. Cai, K. Millican, J. Hoffmann, H. F. Song, J. Aslanides, S. Henderson, R. Ring, S. Young, E. Rutherford, T. Hennigan, J. Menick, A. Cassirer, R. Powell, G. van den Driessche, L. A. Hendricks, M. Rauh, P. Huang, A. Glaese, J. Welbl, S. Dathathri, S. Huang, J. Uesato, J. Mellor, I. Higgins, A. Creswell, N. McAleese, A. Wu, E. Elsen, S. M. Jayakumar, E. Buchatskaya, D. Budden, E. Sutherland, K. Simonyan, M. Paganini, L. Sifre, L. Martens, X. L. Li, A. Kuncoro, A. Nematzadeh, E. Gribovskaya, D. Donato, A. Lazaridou, A. Mensch, J. Lespiau, M. Tsimpoukelli, N. Grigorev, D. Fritz, T. Sottiaux, M. Pajarskas, T. Pohlen, Z. Gong, D. Toyama, C. de Masson d'Autume, Y. Li, T. Terzi, V. Mikulik, I. Babuschkin, A. Clark, D. de Las Casas, A. Guy, C. Jones, J. Bradbury, M. Johnson, B. A. Hechtman, L. Weidinger, I. Gabriel, W. S. Isaac, E. Lockhart, S. Osindero, L. Rimell, C. Dyer, O. Vinyals, K. Ayoub, J. Stanway, L. Bennett, D. Hassabis, K. Kavukcuoglu, and G. Irving. Scaling language models: Methods, analysis & insights from training gopher. CoRR, abs/2112.11446, 2021; Colin Raffel, Noam Shazeer, Adam Roberts, Katherine Lee, Sharan Narang, Michael Matena, Yanqi Zhou, Wei Li, and Peter J Liu. Exploring the limits of transfer learning with a unified text-to-text transformer. arXiv preprint arXiv: 1910.10683, 2019; Daniel Adiwardana, Minh-Thang Luong, David R. So, Jamie Hall, Noah Fiedel, Romal Thoppilan, Zi Yang, Apoorv Kulshreshtha, Gaurav Nemade, Yifeng Lu, and Quoc V. Le. Towards a human-like open-domain chatbot. CoRR, abs/2001.09977, 2020; and Tom B Brown, Benjamin Mann, Nick Ryder, Melanie Subbiah, Jared Kaplan, Prafulla Dhariwal, Arvind Neclakantan, Pranav Shyam, Girish Sastry, Amanda Askell, et al. Language models are few-shot learners. arXiv preprint arXiv: 2005.14165, 2020.

In some implementations, the language model neural network 110 is pre-trained, i.e., trained on a language modeling task that does not require generating alternative Boolean expressions. For example, the training system 100, or a separate training system, pre-trains the language model neural network 110 on a language modeling task, e.g., a task that requires predicting, given a current sequence of text tokens, the next token that follows the current sequence in the training data. The tokens can include any of a variety of tokens that represent text symbols or other symbols. For example, the tokens can include one or more of characters, sub-words, words, punctuation marks, numbers, or other symbols that appear in a corpus of natural language text and/or computer code.

As a particular example, the language model neural network 110 can be pre-trained on a maximum-likelihood objective on a large dataset of text in one or more natural languages, e.g., text that is publicly available from the Internet or another text corpus, a large dataset of computer code in one or more programming languages, e.g., Python, C++, C#, Java, Ruby, PHP, and so on, e.g., computer code that is publicly available from the Internet or another code repository, a large dataset of audio samples, e.g., audio recordings or waveforms that represent the audio recordings, a large dataset of images where each image includes an array of pixels, a large dataset of videos where each video includes a temporal sequence of frames, or a large multi-modal dataset that includes a combination of two or more of these datasets.

The training dataset 120 includes multiple training tuples in the form of (s, R, e). In each training tuple, s represents a Boolean expression (e.g., “(xx′)+y”); e represents an alternative Boolean expression (e.g., “y”), i.e., a target (e.g., simplified) Boolean expression that should be generated by the language model neural network 110 from the Boolean expression included in the training tuple; and R represents is a list of rules that transform the Boolean expression s to the alternative Boolean expression e (e.g., “xx′=>0 (Inverse), 0+y=>y (Identity)”).

In some implementations, the training system 100 can automatically generate the training dataset 120 based on a set of initial Boolean expressions. For example, the training system 100 can receive data specifying the set of initial Boolean expressions as an upload from a remote user of the system over a data communication network, e.g., using an application programming interface (API) made available by the training system 100. As another example, the training system 100 can receive an input from a user specifying which data that is already maintained by the training system 100, or another system that is accessible by the training system 100, specifies the set of initial Boolean expressions.

For each initial Boolean expression included in the set, the training system 100 repeatedly determines whether any rules from a list of known rules of Boolean algebra are applicable to the initial Boolean expression and, if so, applies the applicable rules in an appropriate order to generate an alternative Boolean expression for the initial Boolean expression.

For example, the training system 100 can generate an alternative Boolean expression e for an initial Boolean expression s over multiple steps, where during each step the training system 100 iterates through the list of known rules of Boolean algebra to identify an appropriate rule and applies the identified rule to simplify the Boolean expression as of the step. The simplified Boolean expression that is generated in the last step will then be used as the alternative Boolean expression e for the initial Boolean expression s.

In this example, it the application of a particular rule on an initial Boolean expression s results in a simplified Boolean expression that includes fewer Boolean operators, but nevertheless is logically equivalent (e.g., represents the same logical function) as the initial Boolean expression s, then the particular rule can be identified as an appropriate rule for simplifying the initial Boolean expression s.

The training system 100 can track the rule identified at each step, and then compile the identified rules into a list R for inclusion in a training tuple that also includes the initial Boolean expression s and the alternative Boolean expression e.

Table 1 below shows an example list of known rules of Boolean algebra that can be used by the training system 100 to generate an alternative Boolean expression for an initial Boolean expression.

TABLE 1
Example rules of Boolean algebra.

| Identity Name | AND Form | OR Form |
|---|---|---|
| Identity Law | 1x = x | 0 + x = x |
| Null (or Dominance) Law | 0x = 0 | 1 + x = 1 |
| Idempotent Law | xx = x | x + x = x |
| Inverse Law | xx′ = 0 | x + x′ = 1 |
| Commutative Law | xy = yx | x + y = y + x |
| Associative Law | (xy)z = x(yz) | (x + y) + z = x + (y + z) |
| Distributive Law | x + (yz) = (x + y) (x + z) | x(y + z) = xy + xz |
| Absorption Law | x(x + y) = x | x + xy = x |
| DeMorgan's Law | (xy)′ = x′ + y′ | (x + y)′ = x′y′ |

| | |
|---|---|
| Double Complement Law | x″ = x |

Generally, the training system 100 can train the language model neural network 110 on the training dataset 120 to perform any of a variety of Boolean expression processing tasks based on minimizing a loss function suitable for task.

As a general example, the Boolean expression processing task can be a next token prediction task. For a given training tuple selected from the training dataset 120, the next token prediction task is a task that requires predicting, given a prefix portion of the training tuple, the remaining portion of the training tuple that follows the prefix portion in the training tuple.

A few additional example Boolean expression processing tasks that the language model neural network 110 can be trained to perform are described below.

1. s→e: a simplification task which requires the language model neural network 110 to process a Boolean expression s to generate a prediction of an alternative Boolean expression e.

2. s→R, e: a simplification with rule prediction task which requires the language model neural network 110 to process a Boolean expression s to generate a prediction of an alternative Boolean expression e as well as to generate a predicted list of rules R that can be applied to the Boolean expression s in order to transform it into the alternative Boolean expression e.

3. s, e→R: a rule prediction task which requires the language model neural network 110 to process a Boolean expression s and an alternative Boolean expression e to generate a predicted list of rules R that can be applied to the Boolean expression s in order to transform it into the alternative Boolean expression e.

4. s, e→R: a rule prediction task which requires the language model neural network 110 to process a Boolean expression s and an alternative Boolean expression e to generate a predicted classification output that identifies which rules from a given list of rules R can be applied to the Boolean expression s in order to transform it into the alternative Boolean expression e. Task 4 differs from Task 3 in that Task 4 corresponds to a multi-label classification task, whereas Task 3 corresponds to a regression task (and thus may use different loss functions).

5. s, e, R→P(R): a rule prediction task which requires the language model neural network 110 to process a Boolean expression s, an alternative Boolean expression e, and a given list of rules R to generate a predicted permutation of rules P(R) (where the same sets of rules but in different orders are considered different permutations) from the given list of rules R that can be applied to the Boolean expression s in order to transform it into the alternative Boolean expression e.

More specifically, the training system 100 performs the training over a plurality of update iterations. At each update iteration, the system 100 updates the parameters of the language model neural network 110 using a plurality of training tuples (a “batch” or a “mini-batch” of training tuples) sampled from the training dataset 120.

At each iteration, the training system 100 computes, using the plurality of training tuples, a current gradient of a loss function for any combination of one or more of the tasks mentioned above (or other Boolean expression processing tasks that can be performed on the training tuples) with respect to each of at least some of the parameters 116 of the language model neural network 110.

The loss function generally measures the quality of an output generated by the language model neural network 110 for a given input relative to a target output for the given input for the Boolean expression processing task. For example, the loss function can be a cross-entropy loss function, e.g., a softmax cross-entropy loss function, that measures a difference between (i) the prediction of the alternative Boolean expression e that is generated by the language model neural network 110 from processing a Boolean expression s included in a training tuple and (ii) the alternative Boolean expression e included in the training tuple.

Thus, by repeatedly performing update iterations, the training system 100 repeatedly updates the values of parameters 116 of the language model neural network 110 to determine the updated values of the parameters 116 that will cause the language model neural network 110 to perform well on the Boolean expression processing tasks.

In implementations where the language model neural network 110 is pre-trained, rather than training it from scratch, e.g., from initial values of the parameters 116, the training system 100 can train the language model neural network 110 starting from the pre-trained values of the parameters 116. During training, the training system 100 can incorporate any number of techniques to improve the speed, the effectiveness, or both of the training process.

For example, depending on how, e.g., on which data, which pre-training tasks, and so on, the language model neural network 110 has been pre-trained, the training system 100 can choose between a fine-tuning technique (which generally requires more training tuples) or a few-shot learning technique (which generally requires fewer training tuples) to adapt the pre-trained language model neural network 110 to the Boolean expression processing tasks.

As another example, the training system 100 can adjust the values of only some of the parameters 116 of the language model neural network 110, e.g., the parameters of some of the intermediate layers are held frozen during the training. As another example, the training system 100 can modify the architecture of the pre-trained language model neural network by adding an additional set of parameters, e.g., by way of inserting one or more additional layers or expanding the dimensions of one or more existing layers, and learn the values of those additional set of parameters during the training while the existing parameters are held frozen.

After training, the training system 100 outputs data specifying the trained language model neural network 110, e.g., data specifying at least some of the trained values of the parameters 116 of the language model neural network 110, and, optionally, data specifying the architecture of the language model neural network 110, to an inference system 150.

The inference system 150 then deploys the trained language model neural network 110 on one or more computing devices to perform inference, i.e., to generate new network outputs that each include an alternative Boolean expression 122 from new network inputs that each include a Boolean expression 112.

In some implementations, the inference system 150 is a part of or coupled to electronic design automation (“EDA”) software that can be used at various stages during an integrated circuit design flow. An integrated circuit design flow typically proceeds through the following stages: the creation of a product idea for an integrated circuit, EDA processes including, e.g., logic design, synthesis, and physical implementation, that make use of the EDA system, tape-out (which is when geometric patterns for the integrated circuit are sent to a fabrication facility to manufacture lithography masks), and fabrication (which is when the lithography masks are used in various semiconductor fabrication steps to produce the integrated circuit as an article of manufacture).

More specifically, during logic design, the EDA software facilitates the generation of the specifications for the integrated circuit, e.g., by providing an integrated development environment (IDE) where a user, e.g., a circuit designer, can code the description of the components of the integrated circuit in a hardware description language (“HDL”) such as VHDL, Verilog, or System Verilog through a client device. Such an HDL description may take the form of a logic-level register transfer level (“RTL”) description, a gate-level description, a layout-level description, or a mask-level description.

The HDL description may describe the logical function of each component, e.g., each circuit, of the integrated circuit by using Boolean expressions to define each signal the component produces as a function of the component's input signals and/or of output signals of various registers and other memory devices.

During synthesis, the EDA software converts the HDL description into a gate-level netlist including data representing a set of logic gates (e.g., AND, OR, INV, XOR, XNOR) from a synthesis library which also represents the logical function of the integrated circuit. The gate-level netlist describes the components of the integrated circuit as each being implemented by a set of interconnected logic gates.

Like the HDL description, the gate-level netlist description may similarly describe the logical function of each component of the integrated circuit by using Boolean expressions to define each signal the component produces as a function of the component's input signals and/or of output signals of various registers and other memory devices.

During physical implementation, placement (positioning of circuit components such as transistors or capacitors) and routing (connection of the circuit components by multiple conductors) of the logic gates included in the gate-level netlist take place to produce a data set describing geometric patterns to be applied to lithography masks.

FIG. 1 thus illustrates that the inference system 150 receives, as input, an initial description of an integrated circuit 152 and generates, as output, a modified description of the integrated circuit 154 by using the trained language model neural network 110 based on the initial description of the integrated circuit 152.

The initial and modified descriptions of the integrated circuit 152, 154 can each be any type of design representation, including, but not limited to, a logic-level register transfer level (“RTL”) description or a gate-level description written in a hardware description language (“HDL”) such as VHDL, Verilog, or SystemVerilog, or a gate-level netlist description. As explained above, the initial description of the integrated circuit 152 generally includes Boolean expressions.

As part of the EDA processes that occur during an integrated circuit design flow, the inference system 150 processes each of at least some of the Boolean expressions, e.g., Boolean expression 112, included in the initial description of the integrated circuit 152 to generate a corresponding alternative Boolean expression, e.g., alternative Boolean expression 122, for the Boolean expression for inclusion in the modified description of the integrated circuit 154. The alternative Boolean expression 122 is a simplified representation of the Boolean expression 112. In particular, the alternative Boolean expression 122 is logically equivalent, e.g., represents the same logical function, as the Boolean expression 112, but nevertheless includes a smaller number of Boolean operators than the Boolean expression 112. The modified description of the integrated circuit 154 thus includes a smaller number of Boolean operators than the initial description of an integrated circuit 152.

A logical function represented by a Boolean expression can be implemented by a group of interconnected hardware devices, e.g., where each Boolean operator included in the Boolean expression is implemented by one or more corresponding logic gates. In general, the more logic gates used to implement the logical function represented by each Boolean expression, the more power and area the integrated circuit which can perform the logical function will require. Therefore, reducing the number of logic gates needed to implement the logical functions of an integrated circuit is desirable because this will conserve power consumption and save area of the IC.

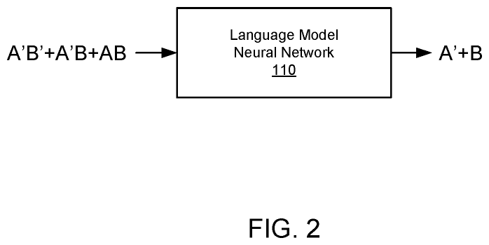

FIG. 2 shows an example illustration of the language model neural network 100 generating a network output that includes an alternative Boolean expression based on processing a network input that includes a Boolean expression. In this example, an initial description of an integrated circuit 152 employs the following Boolean expression to describe the logical function to be performed by a component of an integrated circuit:

$${A}^{′} {B}^{′} + {A}^{′} B + AB \qquad [ 1 ]$$

which includes three AND operators and one three-output OR operator.

Rather than proceeding with an integrated circuit design flow that directly implements the Boolean expression in this example using a total of four logic gates including three AND gates and one three-output OR gate, however, the EDA software that includes or has access to the inference system 150 can generate a modified description of the integrated circuit 154 which is then used in place of the initial description of the integrated circuit 152 in the integrated circuit design flow.

In this example, the modified description of the integrated circuit 154 employs the following alternative Boolean expression to describe the same logical function as the initial description of the integrated circuit 152:

$${A}^{′} + B \qquad [ 2 ]$$

which includes one OR operator. Implementation of this alternative Boolean expression thus uses one OR gate.

In this example, the modified description 154 includes an alternative Boolean expression that preserves the logical function represented by the initial description 152, i.e., the alternative Boolean expression generates the same output given the same input signals A, B, but eliminates the need to use any AND gates, and additionally replaces the three-output OR with the two-input OR gate that is easier to fabricate.

Compared to the initial description 152, the modified description 154 not only reduces the number of gates the integrated circuit will need to perform the logical function, but it also reduces the amount of power resources the integrated circuit will require to perform the logical function.

In this example and many other examples, logic gates implementing the corresponding Boolean operators included in the modified description 154 (instead of the initial description 152) can be subsequently placed and routed during the physical implementation stage of the integrated circuit design flow.

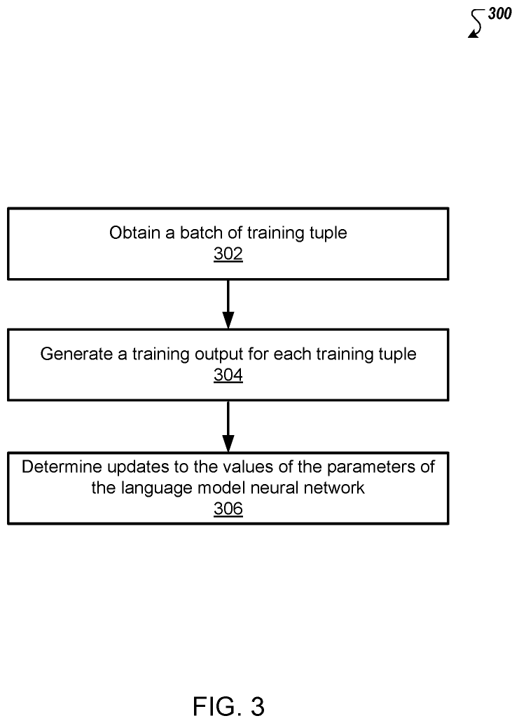

FIG. 3 is a flow diagram of an example process 300 for training a language model neural network to perform one or more Boolean expression processing tasks on a training dataset. For convenience, the process 300 will be described as being performed by a system of one or more computers located in one or more locations. For example, a training system, e.g., the training system 100 of FIG. 1, appropriately programmed, can perform the process 300.

The system can perform iterations of the process 300 on different batches of training tuples to update the values of the parameters of the language model neural network, i.e., to determine trained values of the parameters of the language model neural network.

The system can continue performing iterations of the process 300 until termination criteria for training the language model neural network have been satisfied, e.g., until the parameters have converged, until a threshold amount of wall clock time has elapsed, or until a threshold number of iterations of the process 300 have been performed.

The system obtains a batch of training tuples from the training dataset (step 302). The system will generally obtain different training tuples at different iterations, e.g., by sampling a fixed number of training tuples from a larger number of training tuples at each iteration.

As mentioned above, each training tuple is in the form of (s, R, e), where s represents a Boolean expression, e represents an alternative Boolean expression, i.e., a target Boolean expression that should be generated by the language model neural network from the Boolean expression, and R represents is a list of rules that transform the Boolean expression to the alternative Boolean expression.

For each training tuple included in the batch of training tuples obtained from the training dataset, the system processes the training tuple using the language model neural network, to generate a training output (step 304). In general the system can train the language model neural network to perform any one or more of a variety of Boolean expression processing tasks by processing the same training output, where different tasks require the language model neural network to generate different training outputs.

For example, the tasks can include a simplification task which requires the language model neural network to process a Boolean expression s to generate a training output that includes a prediction of an alternative Boolean expression e.

As another example, the tasks can include a simplification with rule prediction task which requires the language model neural network to process a Boolean expression s to generate a training output that includes a prediction of an alternative Boolean expression e and a predicted list of rules R that can be applied to the Boolean expression s in order to transform it into the alternative Boolean expression e.

As another example, the tasks can include a rule prediction task which requires the language model neural network to process a Boolean expression s and an alternative Boolean expression e to generate a training output that includes a predicted list of rules R that can be applied to the Boolean expression s in order to transform it into the alternative Boolean expression e.

As another example, the tasks can include a rule prediction task which requires the language model neural network to process a Boolean expression s and an alternative Boolean expression e to generate a training output that includes a predicted classification output that identifies which rules from a given list of rules R can be applied to the Boolean expression s in order to transform it into the alternative Boolean expression e.

As another example, the tasks can include a rule prediction task which requires the language model neural network to process a Boolean expression s, an alternative Boolean expression e, and a given list of rules R to generate a training output that includes a predicted permutation of rules P(R) from the given list of rules R that can be applied to the Boolean expression s in order to transform it into the alternative Boolean expression e.

As yet another example, the tasks can include two or more of the tasks mentioned above.

The system determines one or more updates to the values of the parameters of the language model neural network (step 306). The system can do this by computing, for each training tuple in the batch, respective gradients of a loss function with respect to the parameters of the language model neural network by backpropagation through the appropriate parameters of the language model neural network. The system can then determine the updates by applying an update rule, e.g., an Adam update rule, an Rmsprop update rule, or a stochastic gradient descent (SGD) update rule, to the respective gradients.

For example, the loss function can be a cross-entropy loss function, e.g., a softmax cross-entropy loss function, or another loss function that measures the quality of a training output generated by the language model neural network for a given input relative to a target output for the given input for the Boolean expression processing task.

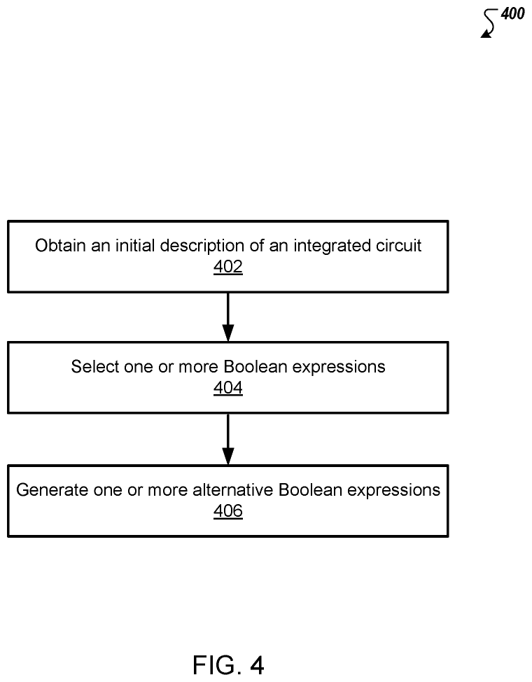

FIG. 4 is a flow diagram of an example process 400 for generating an alternative Boolean expression using a language model neural network. For convenience, the process 400 will be described as being performed by a system of one or more computers located in one or more locations. For example, an inference system, e.g., the inference system 150 of FIG. 1, appropriately programmed, can perform the process 400. Process 400 can generally be performed as part of an integrated circuit design flow to produce an integrated circuit (IC) as an article of manufacture.

The system obtains an initial description of an integrated circuit (IC) (step 402). The initial description of the IC can be any type of design representation, including, but not limited to, a logic-level register transfer level (“RTL”) description or a gate-level description written in a hardware description language (“HDL”) such as VHDL, Verilog, or System Verilog, or a gate-level netlist description.

The initial description of the IC can be obtained in any way. For example, the system can receive, as the initial description of the IC, a logic-level RTL description from a user of the system, e.g., from a circuit designer. As another example, the system can generate, as the initial description of the IC, a gate-level netlist based on the logic-level RTL description. As yet another example, the system can receive, as the initial description of the IC, a gate-level netlist from a user of the system, e.g., from a circuit designer.

The initial description of the IC can include Boolean expressions. For example, the initial description can include a Boolean expression for each component, e.g., each circuit, of the IC, where the Boolean expression defines each signal the component produces as a function of the component's input signals and/or of output signals of various registers and other memory devices.

The system selects one or more Boolean expressions specified in the initial description (step 404). For example, the system can parse the initial description to identify the Boolean expressions.

The system processes an input that includes the one or more selected Boolean expressions using a language model neural network to generate an output (step 406). The language model neural network can have been trained using the training techniques described above in FIG. 3.

In some implementations, the output includes, for each of the one or more selected Boolean expressions, one or more alternative Boolean expressions. Each alternative Boolean expression can be a simplified representation that has fewer Boolean operators than the selected Boolean expression but represents a same logical function as the selected Boolean expression, e.g., the alternative Boolean expression maintains the same logical relationship between output signal and input signals of a component of the IC as the selected Boolean expression.

In some implementations, the output includes, for each alternative Boolean expression, one or more Boolean algebra rules to apply to the selected Boolean expression in order to generate the alternative Boolean expression. In some of these implementations, the one or more Boolean algebra rules are arranged in a determined order of application of the Boolean algebra rules, e.g., a firstly applied Boolean algebra rule is arranged preceding to a subsequently applied Boolean algebra rule.

In some implementations, the output includes both the one or more alternative Boolean expressions and, for each alternative Boolean expression, the one or more Boolean algebra rules to apply to the selected Boolean expression in order to generate the alternative Boolean expression.

In some implementations, after generating the alternative Boolean expression for a selected Boolean expression, the system checks whether the alternative Boolean expression is logically equivalent (e.g., represents the same logical function) as the selected Boolean expression. For example, two Boolean expressions may be considered as functionally equivalent when they have the same output signals when receiving the same input signals.

If so, this means the language model neural network improved the initial description of the IC without changing the function of the IC. The system can then replace the selected Boolean expression originally included in the initial description of the IC with the alternative Boolean expression that has been generated by using the language model neural network. Otherwise, the alternative Boolean expression will be discarded, and the system can, for example, cause the language model neural network to generate another alternative Boolean expression.

By repeatedly performing step 406 for each of at least some of the Boolean expressions included in the initial description and then by replacing the Boolean expressions with the alternative Boolean expressions generated by the language model neural network, the system can modify the initial description of the IC to generate a modified description of the IC.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

In this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework or a JAX framework.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A method performed by one or more computers, the method comprising:
obtaining a description of an integrated circuit (IC);
selecting one or more Boolean expressions specified in the description; and
processing the one or more selected Boolean expressions using a neural network to generate an output that comprises one or more alternative Boolean expressions.

2. The method of claim 1, wherein the description of the integrated circuit comprises a Register Transfer Level (RTL) description or a gate-level netlist description.

3. The method of claim 1, wherein obtaining the description of the IC comprises receiving the description from a client device.

4. The method of claim 1, wherein each alternative Boolean expression is a simplified representation that has fewer Boolean operators than a corresponding Boolean expression but represents a same logical function as the corresponding Boolean expression.

5. The method of claim 1, wherein the output further comprises, for each alternative Boolean expression, one or more Boolean algebra rules to apply to the corresponding Boolean expression to generate the alternative Boolean expression.

6. The method of claim 1, wherein the one or more Boolean algebra rules included in the output are arranged in a determined order of application of the Boolean algebra rules.

7. The method of claim 1, further comprising modifying the description of the integrated circuit by replacing the one or more Boolean expression with the alternative Boolean expressions.

8. The method of claim 7, further comprising providing the modified description for use in fabricating the IC.

9. The method of claim 8, further comprising fabricating the IC based on the modified description.

10. The method of claim 1, wherein the neural network is an auto-regressive language model neural network.

11. The method of claim 10, wherein the auto-regressive language model neural network is pre-trained on text data and then fine-tuned or few-shot learned using a plurality of Boolean expression training tuples, and wherein each Boolean expression training tuple comprises (i) a Boolean expression (ii) a simplified Boolean expression and (iii) a set of one or more Boolean algebra rules to apply to the Boolean expression to generate the simplified Boolean expression.

12. A system comprising one or more computers and one or more storage devices storing instructions that when executed by the one or more computers cause the one more computers to perform operations comprising:
obtaining a description of an integrated circuit (IC);
selecting one or more Boolean expressions specified in the description; and
processing the one or more selected Boolean expressions using a neural network to generate an output that comprises one or more alternative Boolean expressions.

13. The system of claim 12, wherein the description of the integrated circuit comprises a Register Transfer Level (RTL) description or a gate-level netlist description.

14. The system of claim 12, wherein obtaining the description of the IC comprises receiving the description from a client device.

15. The system of claim 12, wherein each alternative Boolean expression is a simplified representation that has fewer Boolean operators than a corresponding Boolean expression but represents a same logical function as the corresponding Boolean expression.

16. The system of claim 12, wherein the output further comprises, for each alternative Boolean expression, one or more Boolean algebra rules to apply to the corresponding Boolean expression to generate the alternative Boolean expression.

17. The system of claim 12, wherein the operations further comprise modifying the description of the integrated circuit by replacing the one or more Boolean expression with the alternative Boolean expressions.

18. The system of claim 17, wherein the operations further comprise providing the modified description for use in fabricating the IC.

19. The system of claim 17, wherein the operations further comprise fabricating the IC based on the modified description.

20. The system of claim 12, wherein the neural network is an auto-regressive language model neural network that has been pre-trained on text data and then fine-tuned or few-shot learned using a plurality of Boolean expression training tuples, and wherein each Boolean expression training tuple comprises (i) a Boolean expression (ii) a simplified Boolean expression and (iii) a set of one or more Boolean algebra rules to apply to the Boolean expression to generate the simplified Boolean expression.

21. One or more computer storage media storing instructions that when executed by one or more computers cause the one more computers to perform operations comprising:
obtaining a description of an integrated circuit (IC);
selecting one or more Boolean expressions specified in the description; and
processing the one or more selected Boolean expressions using a neural network to generate an output that comprises one or more alternative Boolean expressions.
